(19) United States
(12) Patent Application Publication
(10) Pub. No.: US 2016/0043342 A1
(43) Pub. Date: Feb. 11, 2016

(54) FLEXIBLE DISPLAY APPARATUS AND METHOD OF MANUFACTURING THE SAME

(71) Applicant: Samsung Display Co., Ltd., Yongin-City (KR)

(72) Inventors: Byoung-Duk Lee, Yongin-City (KR); Eung-Seok Park, Yongin-City (KR); Won-Min Yun, Yongin-City (KR); Yun-Ah Chung, Yongin-City (KR); Yoon-Hyeung Cho, Yongin-City (KR); Yong-Chan Ju, Yongin-City (KR)

(21) Appl. No.: 14/593,821

(22) Filed: Jan. 9, 2015

(30) Foreign Application Priority Data
Aug. 11, 2014 (KR) 10-2014-0103630

(51) Int. Cl. H01L 51/52; H01L 51/56; H01L 51/00; G06F 1/16; H01L 27/32

(52) U.S. Cl. CPC H01L 51/5237; G06F 1/1652; H01L 27/3248; H01L 51/0097; H01L 51/56; H01L 2227/323

(57) ABSTRACT

Disclosed are a flexible display apparatus and a method of manufacturing the same. The method includes preparing an organic layer material for a thin film encapsulation layer, coating an edge area and a central area of a substrate with the organic layer material by using a plurality of nozzles, and finishing an organic layer for the thin film encapsulation layer on the substrate. An amount of the organic layer material is adjusted by selectively driving a variable adjustment unit of the substrate.

### RELATED APPLICATION

This application claims the benefit of Korean Patent Application No. 10-2014-0103630, filed on Aug. 11, 2014, in the Korean Intellectual Property Office, the disclosure of which is incorporated herein in its entirety by reference.

### BACKGROUND

1. Field

One or more embodiments of the present invention relate to a flexible display apparatus and a method of manufacturing the same.

2. Description of the Related Art

Generally, a display apparatus such as an organic light emitting display apparatus may be applied to mobile devices, such as smartphones, tablet personal computers (PCs), laptop computers, digital cameras, camcorders, and portable information terminals, and electronic/electric products such as ultra-thin televisions (TVs).

Recently, research for manufacturing a slimmed display apparatus is being conducted. In particular, flexible display apparatuses which are easy to carry and are applied to various types of devices are attracting much attention as next-generation display apparatuses.

Flexible display apparatuses based on organic light emitting display technology is the most likely to be used as display apparatuses. The flexible display apparatuses include a thin film encapsulation layer for covering a display unit. The thin film encapsulation layer may have a uniform thickness.

### SUMMARY

One or more embodiments of the present invention include a flexible display apparatus and a method of manufacturing the same.

Additional aspects will be set forth in part in the description which follows and, in part, will be apparent from the description, or may be learned by practice of the presented embodiments.

According to one or more embodiments of the present invention, a method of manufacturing a flexible display apparatus includes: preparing an organic layer material for a thin film encapsulation layer; coating an edge area and a central area of a substrate with the organic layer material by using a plurality of nozzles; and finishing an organic layer for the thin film encapsulation layer on the substrate, wherein an amount of the organic layer material is adjusted by selectively driving a variable adjustment unit of the substrate.

The plurality of the nozzles may be arranged in the edge area and the central area along a first direction of the substrate.

The plurality of nozzles may apply the organic layer material on the edge area and the central area while moving along a second direction intersecting the first direction.

The edge area of the substrate may include an area from a line, from which edge crawling adjacent to the central area starts, to an edge line that is one side edge of the substrate. The variable adjustment unit may be driven, and the organic layer material may be formed by adjusting an amount of the organic layer material in the edge area of the substrate.

Different amounts of the organic layer material may be formed by the variable adjustment unit from the line, from which the edge crawling starts, to the edge line for each of the plurality of nozzles.

An interval at which the organic layer material is formed may be adjusted by varying a frequency of each of the plurality of nozzles from the line, from which the edge crawling starts, to the edge line.

An interval at which the organic layer material may be formed increases in a direction from a nozzle, to which a relatively high frequency is applied, to a nozzle to which a relatively low frequency is applied.

An amount of the organic layer material may be adjusted by varying a voltage of each of the plurality of nozzles from the line, from which the edge crawling starts, to the edge line.

An amount of the coated organic layer material may be reduced in a direction from a nozzle, to which a relatively high voltage is applied, to a nozzle to which a relatively low voltage is applied.

An amount of the organic layer material may be reduced in a direction from the line, from which the edge crawling starts, to the edge line.

The organic layer material may be formed with a constant voltage without driving the variable adjustment unit in the central area of the substrate.

In forming the organic layer to a thickness of 4 μm or more, a difference between a point indicating a highest height in the edge area and a point indicating a lowest height of the central area may be set to 100 nm or less.

The organic layer may be formed by an inkjet process.

According to one or more embodiments of the present invention, a flexible display apparatus includes: a flexible substrate; a display unit that is formed on the flexible substrate; and a thin film encapsulation layer that covers the display unit, and in which at least one organic layer and at least one inorganic layer are stacked, wherein the at least one organic layer of the thin film encapsulation layer is formed to have a thickness difference of 100 nm or less between an edge area and a central area of the flexible substrate.

The edge area of the flexible substrate may include an area from a line, from which edge crawling adjacent to the central area starts, to an edge line that is one side edge of the flexible substrate. The at least one organic layer may be formed to a thickness of 4 μm or more, and a difference between a point indicating a highest height in the edge area and a point indicating a lowest height of the central area may be set to 100 nm or less.

The organic layer may be one selected from epoxy, polyimide, polyethylene terephthalate, polycarbonate, polyethylene, and polyacrylate.

The inorganic layer is one selected from aluminum oxide, zirconium oxide, zinc oxide, titanium oxide, chromium oxide, magnesium oxide, silicon nitride, silicon oxynitride, silicon oxide, and silicon carbide.

The display unit may include: at least one thin film transistor; and a first electrode, an intermediate layer that includes an organic emission layer, and a second electrode, which are electrically connected to the at least one thin film transistor.

The at least one organic layer and the at least one inorganic layer may be directly formed on the display unit.

The at least one organic layer may be formed by an inkjet process.

### BRIEF DESCRIPTION OF THE DRAWINGS

These and/or other aspects will become apparent and more readily appreciated from the following description of the embodiments, taken in conjunction with the accompanying drawings in which:

FIG. 1 is a perspective view illustrating a state in which a flexible display apparatus according to an embodiment of the present invention is unfolded;

FIG. 2 is a perspective view illustrating a state in which the flexible display apparatus of FIG. 1 is bent;

FIG. 3 is a cross-sectional view illustrating one sub-pixel of a flexible display apparatus according to an embodiment of the present invention;

FIG. 4 is a plan view illustrating that an organic layer material is formed on a substrate according to an embodiment of the present invention;

FIG. 5 is a graph showing that an organic layer material is formed on the substrate of FIG. 4;

FIG. 6 is a graph showing, by thickness, that an organic layer material is formed on a substrate according to an embodiment of the present invention;

FIG. 7 is a plan view illustrating that an organic layer material is formed on a substrate according to another embodiment of the present invention;

FIG. 8 is a graph showing that an organic layer material is formed on the substrate of FIG. 7;

FIG. 9 is a schematic block diagram of an inkjet system for coating an organic layer material on a substrate according to an embodiment of the present invention;

FIG. 10 is a flowchart illustrating a method of forming an organic layer material on a substrate according to an embodiment of the present invention;

FIG. 11 is a plan view illustrating that an organic layer material is formed on a substrate according to a comparative example; and

FIG. 12 is a graph showing that an organic layer material is formed on the substrate of FIG. 11.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description.

Since the present embodiments may have diverse modified embodiments, preferred embodiments are illustrated in the drawings and are described in the detailed description. However, this does not limit the present embodiments within specific embodiments and it should be understood that the present invention covers all the modifications, equivalents, and replacements within the idea and technical scope of the present embodiments. Moreover, detailed descriptions related to well-known functions or configurations will be ruled out in order not to unnecessarily obscure subject matters of the present embodiments.

Terms like a first and a second may be used to describe various elements, but the elements should not be limited by the terms. The terms may be used only as object for distinguishing an element from another element.

The terms used in this application, only certain embodiments have been used to describe, is not intended to limit the present embodiments. In the following description, the technical terms are used only for explain a specific exemplary embodiment while not limiting the present embodiments. The terms of a singular form may include plural forms unless referred to the contrary. The meaning of “include,” “comprise,” “including,” or “comprising,” specifies a property, a region, a fixed number, a step, a process, an element and/or a component but does not exclude other properties, regions, fixed numbers, steps, processes, elements and/or components.

Hereinafter, a flexible display apparatus and a method of manufacturing the same according to embodiments of the present invention will be described in detail with reference to the accompanying drawings. Like reference numerals in the drawings denote like elements, and thus their descriptions will not be repeated.

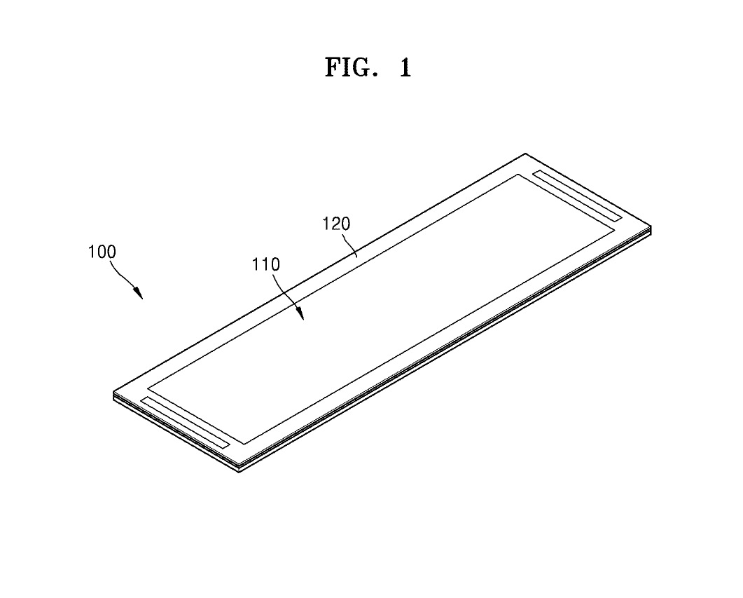

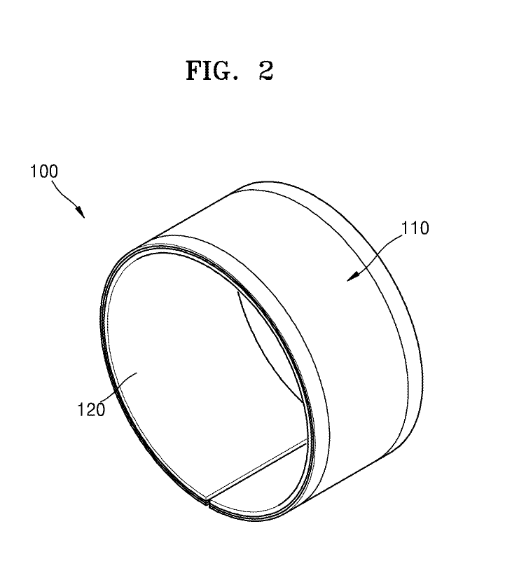

FIG. 1 is a perspective view illustrating a state in which a flexible display apparatus 100 according to an embodiment of the present invention is unfolded, and FIG. 2 is a perspective view illustrating a state in which the flexible display apparatus 100 of FIG. 1 is bent.

In the present embodiment, an organic light emitting display apparatus will be described as an example of the flexible display apparatus 100, but a liquid crystal display (LCD) device, a field emission display apparatus, or an electronic paper display apparatus may be used as the flexible display apparatus 100.

Referring to FIGS. 1 and 2, the flexible display apparatus 100 includes a flexible display panel 110, which displays an image, and a flexible holder 120 in which the flexible display panel 110 is provided. The flexible display panel 110 includes a touch screen and various films such as a polarizer, in addition to a flexible substrate in which a display unit is formed.

The flexible display apparatus 100 may be changed to various shapes such as an unfolded shape, a shape which is bent at a certain angle, or a cylindrically wound shape. A user may watch an image at various viewing angles.

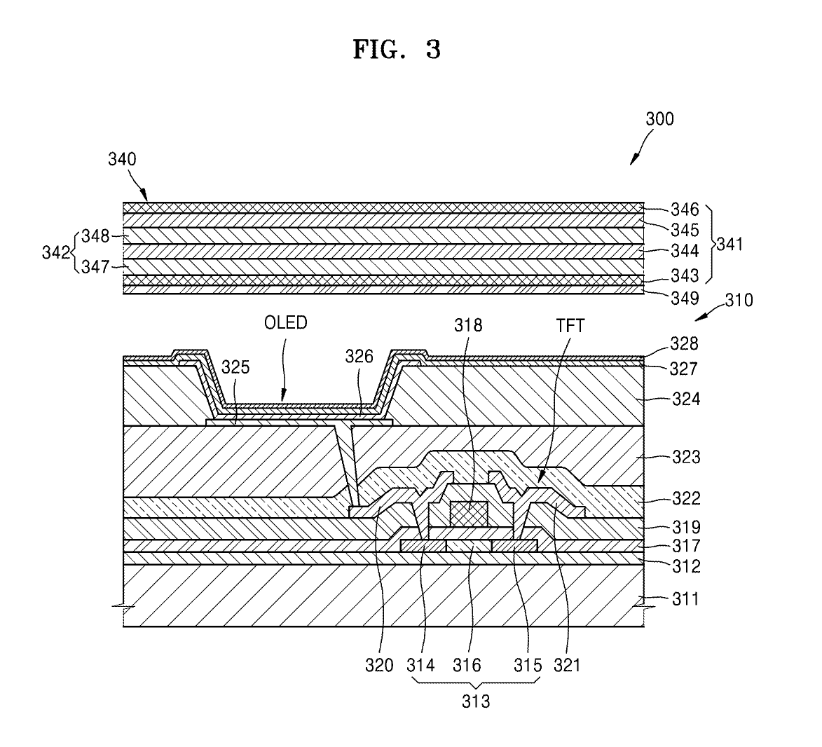

FIG. 3 is a cross-sectional view illustrating one sub-pixel of a flexible display apparatus 300 according to an embodiment of the present invention.

Here, each of a plurality of sub-pixels includes at least one thin film transistor (TFT) and an organic light emitting device (OLED). The TFT may be variously changed in a number and a structure, in addition to a structure of FIG. 3.

Referring to the drawing, the flexible display apparatus 300 includes a display unit 310. The display unit 310 may display an image.

The display unit 310 includes a flexible substrate 311. The flexible substrate 311 may formed of an insulating material having flexibility. For example, the flexible substrate 311 may include a polymer material such as polyimide (PI), polycarbonate (PC), polyethersulphone (PES), polyethylene terephthalate (PET), polyethylenenaphthalate (PEN), polyarylate (PAR), or fiber glass reinforced plastic (FRP). In an embodiment, the flexible substrate 311 may be formed of glass which is flexible and has a thin thickness.

The flexible substrate 311 may be transparent, semi-transparent, or opaque.

A buffer layer 312 may be formed on the flexible substrate 311. The buffer layer 312 smoothens a surface of the flexible substrate 311, and prevents penetration of moisture or external air. The buffer layer 312 may include one selected from an inorganic layer, such as silicon oxide (SiOx), silicon nitride (SiNx), silicon oxynitride (SiOxNy), aluminum oxide (AlOx), or aluminum oxynitride (AlOxNy), and an organic layer such as acryl, polyimide, or polyester. The buffer layer 312 may be formed of a single layer or a multilayer.

The TFT may be formed on the buffer layer 312. The TFT according to the present embodiment exemplifies a TFT having a top gate type, but a TFT having another structure such as a bottom gate type may be provided.

A semiconductor active layer 313 may be formed on the buffer layer 312. A source region 314 and a drain region 315 may be formed by doping an N type impurity ion or a P type impurity ion on the semiconductor active layer 313. A region between the source region 314 and the drain region 315 is a channel region 316 in which impurities are not doped.

The semiconductor active layer 313 may use an inorganic semiconductor, such as amorphous silicon or poly silicon, and an organic semiconductor.

In an embodiment, the semiconductor active layer 313 may be formed of an oxide semiconductor. For example, the oxide semiconductor may include oxide of a material selected from group-4, 12, 13 and 14 metal elements, such as zinc (Zn), indium (In), gallium (Ga), tin (Sn), cadmium (Cd), germanium (Ge), and hafnium (Hf), and a combination thereof.

A gate insulating layer 317 may be deposited on the semiconductor active layer 313. The gate insulating layer 317 may include an inorganic layer such as silicon oxide, silicon nitride, or metal oxide. The gate insulating layer 317 may have a structure of a single layer or a multilayer.

A gate electrode 318 may be formed in a certain region on the gate insulating layer 317. The gate electrode 318 may include a single layer, such as gold (Au), silver (Ag), copper (Cu), nickel (Ni), platinum (Pt), palladium (Pd), aluminum (Al), molybdenum (Mo), or chromium (Cr), and a multilayer. The gate electrode 318 may include an alloy such as Al:Nd or Mo:W.

An interlayer insulating layer 319 may be formed on the gate electrode 318. The interlayer insulating layer 319 may be formed of an inorganic layer such as silicon oxide or silicon nitride. In an embodiment, the interlayer insulating layer 319 may include an organic layer.

A source electrode 320 and a drain electrode 321 are formed on the interlayer insulating layer 319. In detail, by selectively removing the source electrode 320 and the drain electrode 321, a contact hole is formed in the gate insulating layer 317 and the interlayer insulating layer 319. The source electrode 320 is electrically connected to the source region 314 through the contact hole, and the drain electrode 321 is electrically connected to the drain region 315 through the contact hole.

A passivation layer 322 may be formed on the source electrode 320 and the drain electrode 321. The passivation layer 322 may be formed of an inorganic layer, such as silicon oxide or silicon nitride, or an organic layer.

A planarizing layer 323 may be formed on the passivation layer 322. The planarizing layer 323 may include an organic layer such as acryl, polyimide, or benzocyclobutene (BCB).

One selected from the passivation layer 322 and the planarizing layer 323 may be omitted.

An OLED may be formed on the TFT.

The OLED is formed on the planarizing layer 323. The OLED includes a first electrode 325, an intermediate layer 326 including an organic emission layer, and a second electrode 327.

A pixel defining layer 324 covers the planarizing layer 323 and a portion of the first electrode 325. The pixel defining layer 324 may be formed of an organic layer or an inorganic layer. For example, the pixel defining layer 324 may be formed of an organic material, such as polyimide, polyamide, BCB, acryl resin, or phenol resin, or an inorganic material such as SiNx. The pixel defining layer 324 may be formed of a single layer or a multilayer.

A hole and an electron, which are respectively injected from the first electrode 325 and the second electrode 327, may be combined with each other in the intermediate layer 326 to emit light.

The intermediate layer 326 may include the organic emission layer. As another optional example, the intermediate layer 326 includes the organic emission layer, and may further include at least one selected from a hole injection layer (HIL), a hole transport layer (HTL), an electron transport layer (ETL), and an electron injection layer (EIL). However, the present embodiment is not limited thereto. For example, the intermediate layer includes the organic emission layer, and may further include other various functional layers.

The intermediate layer 326 may be formed on the first electrode 325.

The first electrode 325 may be patterned in units of a pixel, and the second electrode 327 may be formed in order for a common voltage to be applied thereto in all pixels.

The first electrode 325 and the second electrode 327 may include a transparent electrode or a reflective electrode.

The first electrode 325 functions as an anode, and may be formed of various conductive materials. The first electrode 325 may be formed of a transparent electrode or a reflective electrode.

For example, when the first electrode 325 is used as the transparent electrode, the first electrode 325 includes a transparent conductive layer such as indium tin oxide (ITO), indium zinc oxide (IZO), zinc oxide (ZnO), or indium oxide (In₂O₃). When the first electrode 325 is used as the reflective electrode, the first electrode 325 forms a reflective layer by using Ag, Mg, Al, Pt, Pd, Au, Ni, Nd, Ir, Cr and a compound thereof, and a transparent conductive layer such as ITO, IZO, ZnO, or In₂O₃ may be formed on the reflective layer.

The second electrode 327 may function as a cathode. Similarly to the first electrode 325, the second electrode 327 may be formed of a transparent electrode or a reflective electrode.

For example, when the second electrode 327 is used as the transparent electrode, metal (i.e., lithium (Li), calcium (Ca), LiF/Ca, LiF/Al, Al, Mg, and a compound thereof) having a low work function may be deposited on the intermediate layer 326, and a transparent conductive layer such as ITO, IZO, ZnO, or In₂O₃ may be further formed on the metals and the compound thereof. When the second electrode 327 is used as the reflective electrode, the second electrode 327 may be formed of Li, Ca, LiF/Ca, LiF/Al, Al, Mg, and a compound thereof.

The first electrode 325 may function as the anode, and the second electrode 327 may function as the cathode. However, the present embodiment is not limited thereto. For example, the first electrode 325 may function as the cathode, and the second electrode 327 may function as the anode.

Each of a plurality of the OLEDs may configure one pixel, and red, green, blue, or white may be realized in each pixel. However, the present disclosure is not limited thereto. The intermediate layer 326 may be formed in common in an entirety of the first electrode 325 irrespective of a position of one pixel. In this case, the organic emission layer may be formed by vertically stacking, for example, a plurality of layers including respective light emitting materials which emit red light, green light, and blue light, or may be formed by mixing a plurality of light emitting materials which respectively emit red light, green light, and blue light. When white light is emitted, it is possible to combine different colors. A color filter or a color conversion layer which converts emitted white light into a certain color may be further formed.

A capping layer 328 for protecting the OLED may be further formed on the second electrode 327.

A thin film encapsulation layer 340 may be formed on the OLED. The thin film encapsulation layer 340 is formed for protecting the intermediate layer 326 and another thin layer from external moisture or oxygen.

The thin film encapsulation layer 340 may have a structure in which at least one inorganic layer 341 and at least one organic layer 342 are stacked. For example, the inorganic layer 341 may include a first inorganic layer 343, a second inorganic layer 344, a third inorganic layer 345, and a fourth inorganic layer 346. The organic layer 342 may include a first organic layer 347 and a second organic layer 348. A halogenation metal layer 349 including LiF may be further formed between the capping layer 328 and the first inorganic layer 343.

In the present embodiment, the halogenation metal layer 349 including LiF, the first inorganic layer 343 including first AlOx, the first organic layer 347 including a first monomer, the second inorganic layer 344 including first SiNx, the second organic layer 348 including a second monomer, the third inorganic layer 345 including second SiNx, and the fourth inorganic layer 346 including second AlOx may be sequentially stacked in the thin film encapsulation layer 340 in a direction deviating from a portion opposite to the OLED.

The halogenation metal layer 349 including LiF is a buffer layer that protects an organic emission layer 330 including the capping layer 328 from strong plasma which is generated when depositing the first inorganic layer 343. The halogenation metal layer 349 may be deposited by using an evaporator.

The first inorganic layer 343 including the first AlOx may be deposited by a sputtering process. The halogenation metal layer 349 and the first inorganic layer 343 may distribute a gas such as H₂O or O₂.

The first organic layer 347 including the first monomer planarizes a lower layer, and acts as particle coverage. The first organic layer 347 may be formed by an inkjet process.

The second inorganic layer 344 including the first SiNx acts as a main barrier layer. The second inorganic layer 344 prevents penetration of H₂O or O₂. The second inorganic layer 344 may be deposited by a chemical vapor deposition (CVD) process.

The second organic layer 348 including the second monomer planarizes a lower layer, and acts as particle coverage. The second organic layer 348 may be formed by the inkjet process.

The third inorganic layer 345 including second SiNx performs a function of a barrier, and prevents penetration of H₂O or O₂. The third inorganic layer 345 may be deposited by the CVD process.

The fourth inorganic layer 346 including the second AlOx may be deposited by the sputtering process.

The inorganic layer 341 may be metal oxide, for example, aluminum oxide (AlOx), zirconium oxide (ZrOx), zinc oxide (ZnOx), titanium oxide (TiOx), chromium oxide (CrO), or MgO, or may be one selected from silicon nitride (SiNx), silicon oxynitride (SiOxNy), silicon oxide (SiOx), and silicon carbide (SiCx).

The organic layer 342 may be one selected from epoxy, polyimide (PI), PET, polycarbonate (PC), polyethylene (PE), and polyacrylate.

In the thin film encapsulation layer 340, the inorganic layer 341 may have a structure having at least two layers, and the organic layer 342 may have a structure having at least one layer. In the thin film encapsulation layer 340, an uppermost layer 346 exposed to the outside may be formed of an inorganic layer so as to prevent moisture from penetrating into the OLED.

The inorganic layer 341 and the organic layer 342, which are included in the thin film encapsulation layer 340, may be directly stacked on the flexible substrate 311 in which the display unit 310 is formed.

In this case, the inorganic layer 341 may be formed by the CVD process. The organic layer 342 may be formed by a vacuum flash evaporation process or the inkjet process.

When the organic layer 342 is formed by a deposition process, the organic layer 342 is deposited by using a mask. Therefore, the mask and a deposition-preventive plate may be periodically replaced, and an additional process may be performed for preventing a monomer from being spread at a lower end edge of the mask. Also, a use efficiency of an organic layer material is not good.

When the organic layer 342 is formed by the inkjet process so as to solve such problems, an edge crawling phenomenon occurs in which a thickness of the organic layer 342 increases in an edge area in comparison with a central area in which the organic layer 342 is formed. The edge crawling phenomenon may be recognized as mura in edge of display unit 310.

In the present embodiment, the organic layer 342 may be formed by using a variable adjustment unit so as to minimize the edge crawling phenomenon.

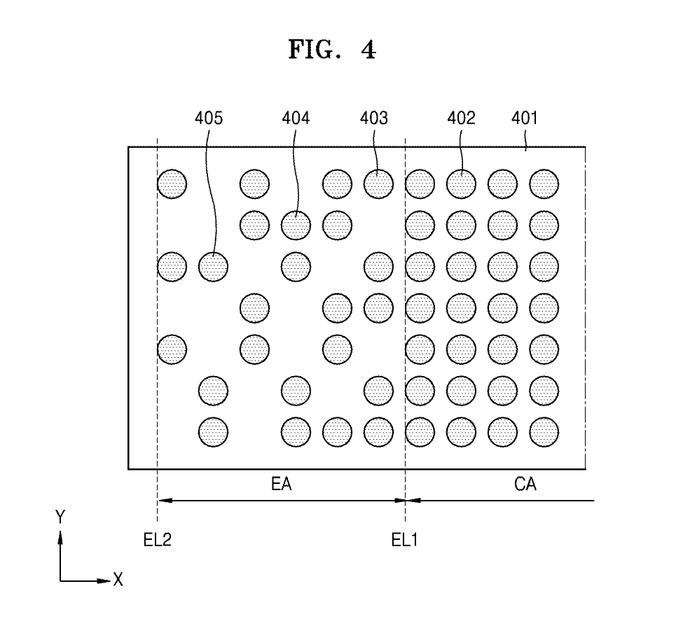

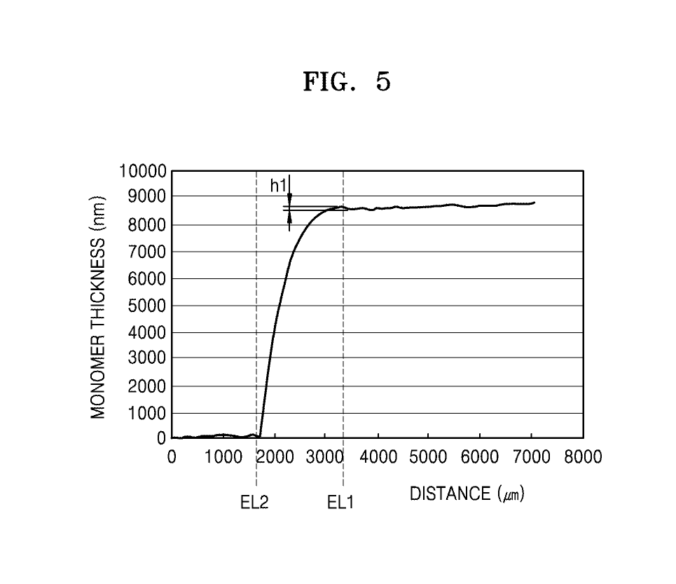

FIG. 4 is a plan view illustrating that an organic layer material is formed on a substrate 401 according to an embodiment of the present invention, and FIG. 5 is a graph showing that a thickness of the organic layer material formed on the substrate 401 of FIG. 4.

Referring to FIGS. 4 and 5, a plurality of liquid droplets 402 to 405 of an organic layer material for thin layer deposition may be formed on the substrate 401 by the inkjet process. In an embodiment, the substrate 401 may be a flexible substrate in which a display unit is formed. In other words, the structure such as the display unit 310 shown in FIG. 3 may be the substrate 401.

A central area CA and an edge area EA which extends outward from the central area CA may be formed in the substrate 401. The edge area EA includes an area from a line EL1, from which edge crawling adjacent to the central area CA starts, to an edge line EL2 that is one side edge of the substrate 401. Although not shown, the edge area EA may extend outward from the central area CA, and may be formed at one side of the substrate 401 which is opposite to the other side of the substrate 401.

A plurality of nozzles may be disposed along an X-axis direction (a horizontal direction of FIG. 4) of the substrate 401 so that the liquid droplets 402 to 405 formed on the substrate 401 are formed by the nozzles. The plurality of nozzles may apply the liquid droplets 402 to 405 on the substrate 401 while moving in a Y-axis direction (a longitudinal direction of FIG. 4) of the substrate 401.

The liquid droplet 402 of the organic layer material for thin layer deposition may be uniformly formed in the central area CA of the substrate 401. On the other hand, the edge crawling phenomenon occurs in the edge area EA of the substrate 401 due to a discharge amount deviation of the liquid droplets 403 to 405 discharged from the nozzles.

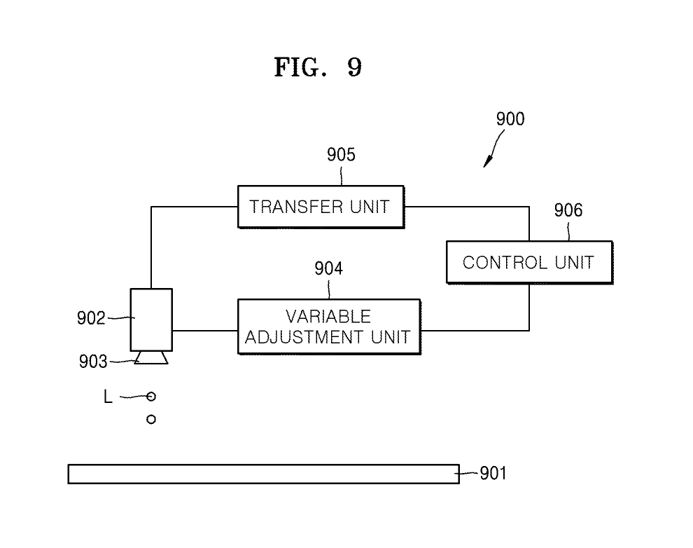

In order to minimize the edge crawling phenomenon, a discharged liquid droplet amount of the organic layer material is adjusted by adjusting the edge area EA with the variable adjustment unit (shown in FIG. 9).

In detail, different amounts of the liquid droplets 403 to 405 of the organic layer material are formed by the variable adjustment unit from the line EL1, from which the edge crawling adjacent to the central area CA starts, to the edge line EL2 that is one side edge of the substrate 401 for each nozzle.

That is, an interval at which the liquid droplets 403 to 405 of the organic layer material are formed is adjusted by varying a frequency applied to each nozzle from the line EL1, from which the edge crawling starts, to the edge line EL2. Therefore, a liquid droplet amount of the organic layer material is adjusted. Herein, the frequency applied to each nozzle means the frequency of injections of material discharged through each nozzle. In other words, the material is discretely discharged with a time interval while the plurality of nozzles moves together in the Y-axis direction. Different frequencies are applied to the nozzles arranged along the X-axis to adjust injection intervals of the material depending on the position along the X-axis. An interval at which the liquid droplet of the organic layer material is formed increases in a direction from a nozzle, to which a relatively high frequency is applied, to a nozzle to which a relatively low frequency is applied. In other words, an interval between liquid droplets along the Y-axis increases with a lower frequency, and an interval between liquid droplets along the Y-axis decreases with a higher frequency.

For example, as illustrated in FIG. 4, five first liquid droplets 403 are formed by applying a relatively high frequency in an area which is disposed adjacent to the line EL1 from which the edge crawling starts, and four second liquid droplets 404 and three third liquid droplets 405 are formed by gradually lowering an applied frequency in a direction from an area, in which the first liquid droplet 403 is formed, to the edge line EL2. Herein, the edge crawling phenomenon means that the thickness of the organic layer in an edge area EA of a substrate increases more than the thickness of the organic layer in a center area CA of the substrate. Edge crawling can be easily observed by a one of ordinary skill in the art or detected by using some equipment.

An amount of liquid droplet is adjusted by increasing an interval between the discharged liquid droplets in a direction, from the line EL1, from which the edge crawling starts, to the edge line EL2.

According to an experiment of the applicant, when an organic layer is formed on the substrate 401 to have a thickness of the organic layer of about 8 μm by varying a frequency in an edge area EA, as shown in FIG. 5, a height difference h1 is 50 nm or less in an edge area (an area from EL1 to EL2) having an interval of 1.2 mm. The height difference h1 corresponds to a difference between a point, indicating a highest height in the edge area EA, and a point indicating a lowest height of the central area CA. 50 nm is a numerical value in which mura caused by a non-uniform thickness is not recognized.

The liquid droplet 402 of the organic layer material for thin layer deposition is formed by applying a constant voltage without driving the variable adjustment unit in the central area CA of the substrate 401 unlike the edge area EA.

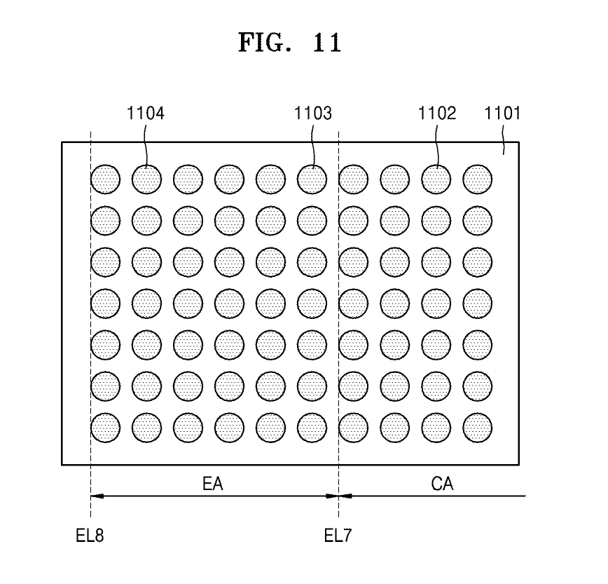

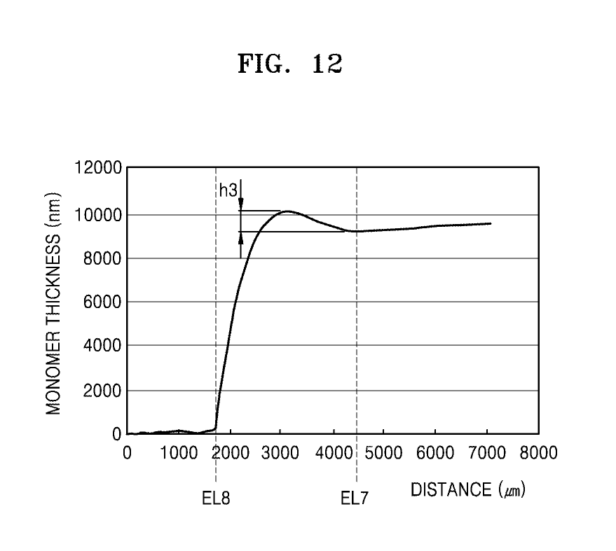

A result, which is obtained by applying the organic layer material for thin layer deposition without driving the variable adjustment unit according to a comparative example, is as shown in FIGS. 11 and 12.

Referring to FIGS. 11 and 12, liquid droplets 1102 to 1104 of an organic layer material for thin layer deposition are formed in a central area CA of a substrate 1101 and an edge area EA, which extends outward from the edge area EA, without varying a frequency or a voltage. In this case, the edge area EA includes an area from a line EL7, from which edge crawling adjacent to the central area CA starts, to an edge line EL8 that is one side edge of the substrate 1101.

According to an experiment of the applicant, when an organic layer is formed on the substrate 1101 to have a thickness of about 8 μm without driving a variable adjustment unit in the central area CA and the edge area EA, a height difference h3 is 831 nm in an edge area (an area from EL7 to EL8) having an interval of 2.6 mm. The height difference h3 corresponds to a difference between a point, indicating a highest height in the edge area EA, and a point indicating a lowest height of the central area CA.

Comparing FIG. 5 with FIG. 12, it may be seen that in forming an organic layer of a thin film encapsulation layer having a uniform thickness, a difference between a point indicating a highest height in the edge area EA and a point indicating a lowest height of the central area CA is far smaller in a case, where the organic layer material is formed in the edge area EA by driving a variable adjustment unit according to the present embodiment, than a case where the organic layer material is formed without driving a variable adjustment unit according to a comparative example.

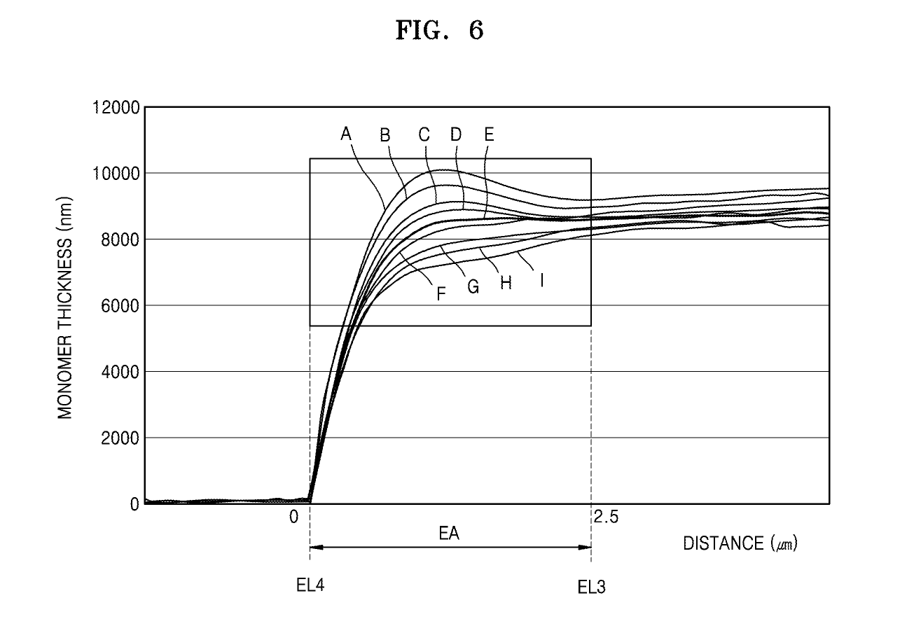

FIG. 6 is a graph showing, by thickness, that an organic layer material is formed on a substrate according to an embodiment of the present invention.

The graph of FIG. 6 shows thickness cross-sectional views by distance which are compensated for by varying frequencies in an edge area EA (i.e., from a line EL3, from which edge crawling starts, to an edge line EL4), in which an organic layer material is formed, to locally decrease an amount of an organic layer material, for solving a phenomenon in which a thickness is not uniform in the edge area EA of a substrate in forming an organic layer of a thin film encapsulation layer. Herein, EL4=EL2 and EL3=EL1.

Referring to the drawing, A to I curves represent edge compensation application distances, and compensation application distances of an edge area are 0 mm (the A curve), 0.3 mm (the B curve), 0.6 mm (the C curve), 0.9 mm (the D curve), 1.2 mm (the E curve), 1.5 mm (the F curve), 1.8 mm (the G curve), 2.1 mm (the H curve), and 2.5 mm (the I curve) in the order of the A curve to the I curve. In this case, that the compensation application distance is 0 mm is a case in which a variable frequency is not applied, and an applied variable frequency increases in a direction from the B curve to the I curve. Herein, a compensation application distance means a distance to adjust a discharge liquid droplet amount of the organic layer materials.

When an organic layer is formed on the substrate 1101 to have a thickness of about 8 μm, it may be seen that a height difference between an edge area and a central area is minimized in application from the edge area to 1.2 mm (the E curve), and thus, an edge crawling phenomenon is minimized.

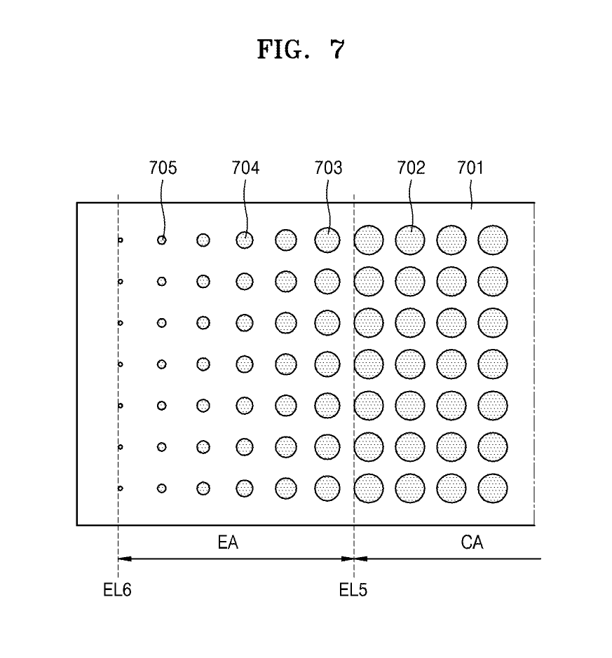

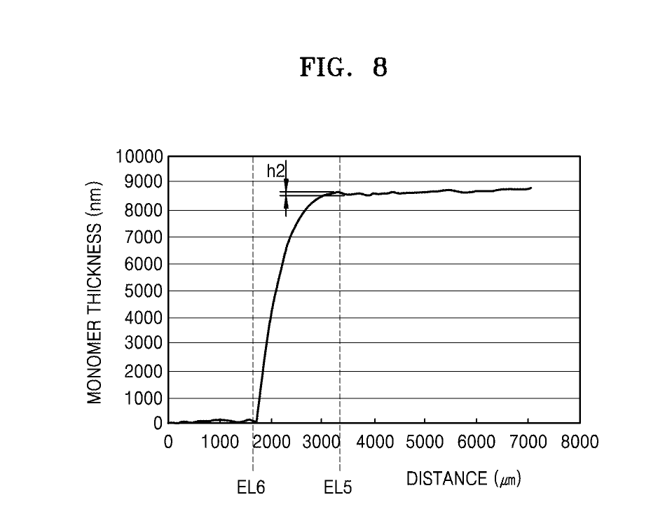

FIG. 7 is a plan view illustrating that an organic layer material is formed on a substrate 701 according to another embodiment of the present invention, and FIG. 8 is a graph showing that an organic layer material is formed on the substrate 701 of FIG. 7.

Referring to FIGS. 7 and 8, a plurality of liquid droplets 702 to 705 of an organic layer material for thin layer deposition may be formed on the substrate 701 by the inkjet process. In an embodiment, the substrate 701 may be a flexible substrate in which a display unit is formed.

A central area CA and an edge area EA, which extends outward from the central area CA and includes an area from a line EL5, from which edge crawling adjacent to the central area CA starts, to an edge line EL6 that is one side edge of the substrate 701, may be formed in the substrate 401.

A plurality of nozzles may be disposed in an X axis direction (a horizontal direction of FIG. 7) of the substrate 701 so that the liquid droplets 702 to 705 formed on the substrate 701 are formed by the nozzles. The plurality of nozzles may coat the liquid droplets 702 to 705 on the substrate 701 while moving in a Y axis direction (a longitudinal direction of FIG. 7) of the substrate 701.

The liquid droplet 702 of the organic layer material for thin layer deposition may be uniformly formed by applying a constant voltage without driving the variable adjustment unit in the central area CA of the substrate 701.

On the other hand, since an edge crawling phenomenon occurs in the edge area EA, a discharged liquid droplet amount of the organic layer material is adjusted by the variable adjustment unit in the edge area EA.

In detail, different amounts of the liquid droplets 702 to 705 of the organic layer material are formed by the variable adjustment unit from the line EL5, from which the edge crawling adjacent to the central area CA starts, to the edge line EL6 that is one side edge of the substrate 701 for each nozzle.

That is, the amounts of the liquid droplets 702 to 705 of the organic layer material are adjusted by varying a frequency applied to each nozzle from the line EL5, from which the edge crawling starts, to the edge line EL6. A coated liquid droplet amount of the organic layer material is reduced in a direction from a nozzle, to which a relatively high frequency is applied, to a nozzle to which a relatively low frequency is applied.

For example, as illustrated in FIG. 7, a first liquid droplet 703 having a first size is formed by applying a relatively high voltage in an area which is disposed adjacent to the line EL1 from which the edge crawling starts, and a second liquid droplet 704 and a third liquid droplet 705 are formed by gradually lowering an applied voltage in a direction from an area, in which the first liquid droplet 703 is formed, to the edge line EL6. In this case, a size of the second liquid droplet 704 is less than that of the first liquid droplet 703, and a size of the third liquid droplet 705 is less than or equal to that of the second liquid droplet 704.

An amount of coated liquid droplet may be adjusted by decreasing a discharged liquid droplet size of the organic layer material in a direction from the line EL5, from which the edge crawling starts, to the edge line EL6.

According to an experiment of the applicant, when an organic layer is formed on the substrate 701 to have a thickness of about 8 μm by varying a frequency in an edge area EA, as shown in FIG. 8, a height difference h2 is 50 nm or less in an edge area (an area from EL5 to EL6) having an interval of 1.2 mm. The height difference h2 corresponds to a difference between a point, indicating a highest height in the edge area EA, and a point indicating a lowest height of the central area CA.

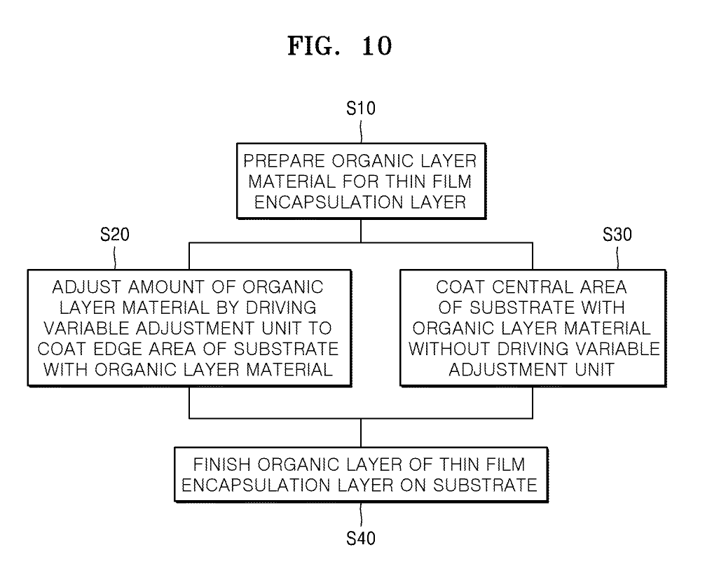

FIG. 9 is a schematic block diagram of an inkjet system for coating an organic layer material on a substrate 901 according to an embodiment of the present invention, and FIG. 10 is a flowchart illustrating a method of forming an organic layer material on a substrate 901 according to an embodiment of the present invention.

Referring to FIGS. 9 and 10, an organic layer material for a thin film encapsulation layer is prepared in operation S10. The organic layer material may be a liquid material selected from epoxy, polyimide (PI), PET, polycarbonate (PC), polyethylene (PE), and polyacrylate.

A liquid droplet L of the organic layer material may be discharged onto the substrate 901 through nozzles 903 which is disposed at an end of a header unit 902. In this case, a plurality of the nozzles 903 may be arranged in a central area and an edge area along a first direction of the substrate 901. The nozzles 903 may apply the organic layer material on the central area and the edge area while the nozzles 903 moves together by a transfer unit 905 along a second direction intersecting the first direction of the substrate 901.

Subsequently, the organic layer material is formed in the edge area and central area of the substrate 901 by using the plurality of nozzles 903.

During the coating processes of the organic material, in operation S20, a control unit 906 adjusts an amount of the organic layer material by driving a variable adjustment unit 904 in the edge area of the substrate 901, thereby applying the organic layer material on the substrate 901.

In the edge area of the substrate 901, different amounts of the organic layer material are applied by the variable adjustment unit 904 from a line, from which edge crawling starts, to an edge line for each of the nozzles 903. An amount of the organic layer material is adjusted by changing a variable voltage of each nozzle 903, or the variable adjustment unit 904 is driven by changing the variable voltage of each nozzle 903 to adjust an interval at which the organic layer material is formed. Herein, “by changing the variable voltage of each nozzle” means that different voltages are respectively applied to the nozzles.

On the other hand, in operation S30, the organic layer material is formed on the substrate 901 by applying a constant voltage without driving the variable adjustment unit 904 in the central area of the substrate 901.

Therefore, in forming an organic layer to have a thickness of 4 μm or more, a difference between a point indicating a highest height in the edge area of the substrate 901 and a point indicating a lowest height of the central area may be set to 100 nm or less.

In operation S40, an amount of the organic layer material is adjusted by selectively driving the variable adjustment unit 904 of the substrate 901 to finish an organic layer of a thin film encapsulation layer on the substrate 901. Herein, “to finish” means performing some other processes to complete the organic layer. These some other processes are general processes including a dry process.

As described above, in the flexible display apparatus and the method of manufacturing the same according to the embodiments of the present invention, an organic layer of a thin film encapsulation layer which has a uniform thickness in a central area and an edge area of a substrate is formed.

It should be understood that the exemplary embodiments described therein should be considered in a descriptive sense only and not for purposes of limitation. Descriptions of features or aspects within each embodiment should typically be considered as available for other similar features or aspects in other embodiments.

While one or more embodiments of the present invention have been described with reference to the figures, it will be understood by those of ordinary skill in the art that various changes in form and details may be made therein without departing from the spirit and scope of the present invention as defined by the following claims.

What is claimed is:

1. A method of manufacturing a flexible display apparatus, the method comprising:
preparing an organic layer material for a thin film encapsulation layer;
coating an edge area and a central area of a substrate with the organic layer material by using a plurality of nozzles; and
finishing an organic layer for the thin film encapsulation layer on the substrate, wherein an amount of the organic layer material is adjusted along one direction of the substrate by selectively driving a variable adjustment unit of the substrate.

2. The method of claim 1, wherein the plurality of the nozzles are arranged in the edge area and the central area along a first direction of the substrate.

3. The method of claim 2, wherein the plurality of nozzles apply the organic layer material on the edge area and the central area while moving along a second direction intersecting the first direction.

4. The method of claim 2, wherein, the edge area of the substrate comprises an area from a line, from which edge crawling adjacent to the central area starts, to an edge line that is one side edge of the substrate, and the variable adjustment unit is driven, and the organic layer material is formed by adjusting an amount of the organic layer material in the edge area of the substrate.

5. The method of claim 4, wherein different amounts of the organic layer material are formed by the variable adjustment unit from the line, from which the edge crawling starts, to the edge line for each of the plurality of nozzles.

6. The method of claim 5, wherein an interval at which the organic layer material is formed is adjusted by varying a frequency of each of the plurality of nozzles from the line, from which the edge crawling starts, to the edge line.

7. The method of claim 6, wherein an interval at which the organic layer material is formed increases in a direction from a nozzle, to which a relatively high frequency is applied, to a nozzle to which a relatively low frequency is applied.

8. The method of claim 5, wherein an amount of the organic layer material is adjusted by varying a voltage of each of the plurality of nozzles from the line, from which the edge crawling starts, to the edge line.

9. The method of claim 8, wherein an amount of the coated organic layer material is reduced in a direction from a nozzle, to which a relatively high voltage is applied, to a nozzle to which a relatively low voltage is applied.

10. The method of claim 9, wherein an amount of the organic layer material is reduced in a direction from the line, from which the edge crawling starts, to the edge line.

11. The method of claim 2, wherein the organic layer material is formed with a constant voltage without driving the variable adjustment unit in the central area of the substrate.

12. The method of claim 4, wherein in forming the organic layer to a thickness of 4 μm or more, a difference between a point indicating a highest height in the edge area and a point indicating a lowest height of the central area is set to 100 nm or less.

13. The method of claim 1, wherein the organic layer is formed by an inkjet process.

14. A flexible display apparatus comprising:
a flexible substrate;
a display unit that is formed on the flexible substrate; and
a thin film encapsulation layer that covers the display unit, and in which at least one organic layer and at least one inorganic layer are stacked, wherein the at least one organic layer of the thin film encapsulation layer is formed to have a thickness difference of 100 nm or less between an edge area and a central area of the flexible substrate.

15. The flexible display apparatus of claim 14, wherein, the edge area of the flexible substrate comprises an area from a line, from which edge crawling adjacent to the central area starts, to an edge line that is one side edge of the flexible substrate, the at least one organic layer is formed to a thickness of 4 μm or more, and a difference between a point indicating a highest height in the edge area and a point indicating a lowest height of the central area is set to 100 nm or less.

16. The flexible display apparatus of claim 14, wherein the organic layer is one selected from epoxy, polyimide, polyethylene terephthalate, polycarbonate, polyethylene, and polyacrylate.

17. The flexible display apparatus of claim 14, wherein the inorganic layer is one selected from aluminum oxide, zirconium oxide, zinc oxide, titanium oxide, chromium oxide, magnesium oxide, silicon nitride, silicon oxynitride, silicon oxide, and silicon carbide.

18. The flexible display apparatus of claim 14, wherein the display unit comprises:
at least one thin film transistor; and
a first electrode, an intermediate layer that includes an organic emission layer, and a second electrode, which are electrically connected to the at least one thin film transistor.

19. The flexible display apparatus of claim 14, wherein the at least one organic layer and the at least one inorganic layer are directly formed on the display unit.

20. The method of claim 14, wherein the at least one organic layer is formed by an inkjet process.
